(19) United States
(12) Patent Application Publication
(10) Pub. No.: US 2023/0406045 A1
(43) Pub. Date: Dec. 21, 2023

(54) METHOD AND DEVICE FOR DETERMINING A VALIDITY OF A TIRE PARAMETER

(71) Applicant: Continental Automotive Technologies GmbH, Hannover (DE)

(72) Inventor: Matthias Kretschmann, Wenzenbach (DE)

(73) Assignee: Continental Automotive Technologies GmbH, Hannover (DE)

(21) Appl. No.: 18/036,508

(22) PCT Filed: Oct. 21, 2021
(86) PCT No.: PCT/DE2021/200160

§ 371 Date: May 11, 2023

(30) Foreign Application Priority Data
Nov. 13, 2020 (DE) 10 2020 214 321.8

(51) Int. Cl. B60C 11/24; B60C 19/00

(52) U.S. Cl. CPC B60C 11/246; B60C 19/00; B60C 2019/004

(57) ABSTRACT

A method for determining a validity of a tire parameter of a tire of a vehicle including: detecting the tire parameter, detecting a value of a validity parameter, the validity parameter being a measure of the validity of the tire parameter, and determining that the detected tire parameter is valid if the detected value of the validity parameter is changed compared to a previous value of the validity parameter.

### CROSS-REFERENCE TO RELATED APPLICATIONS

The present application is a National Stage Application under 35 U.S.C. § 371 of International Patent Application No. PCT/DE2021/200160 filed on Oct. 21, 2021, and claims priority from German Patent Application No. 10 2020 214 321.8 filed on Nov. 13, 2020, in the German Patent and Trade Mark Office, the disclosures of which are herein incorporated by reference in their entireties.

### BACKGROUND

### 1. Field

Modern vehicles usually have devices for monitoring various tire parameters of a vehicle tire such as, for example, a tire pressure, a tire tread depth or other tire parameters. As a general rule, such devices assume that the supplied tire parameters are correct and may be used, without restrictions, for further analysis and/or use.

### 2. Description of Related Art

However, it has been shown that the validity of such tire parameters is not always a given. Thus, it can be that the device does indeed receive a tire parameter, but that this tire parameter is not valid or is invalid under certain circumstances and should therefore not be used for further use. If such a tire parameter which is not valid were nevertheless used, an incorrect result could be established and/or incorrect conclusions could be drawn. This is to be avoided if at all possible.

### SUMMARY

Aspects of embodiments of the present application relate to a method as well as a device for determining a validity of a tire parameter of a tire of a vehicle.

According to a first aspect of an embodiment, there is provided a method for determining a validity of a tire parameter of a tire of a vehicle. The tire parameter can, for example, be a reference tire tread depth which is required to establish an estimated tire tread depth of the tire. Of course, other tire parameters are also conceivable. The method comprises the following steps: detecting the tire parameter, detecting a value of a validity parameter, the validity parameter being a measure of the validity of the detected tire parameter, and determining that the detected tire parameter is valid if the detected value of the validity parameter is changed compared to a previous value of the validity parameter. The validity parameter can be regarded as being a form of additional information for the detected tire parameter. This additional information, which is inherent in the tire parameter and is transmitted, for example, together with the tire parameter to an electronic control system, makes it possible to evaluate this tire parameter. The “valid” evaluation means, for example, that the tire parameter can be trusted. If the tire parameter is “not valid”, then this means that the tire parameter cannot be trusted. The consequence of this is, e.g., that the electronic control system, due to the transmitted additional information, does not use the tire parameter, and/or does not take account of the tire parameter, e.g., for continuing analyses which would be based on the detected tire parameter.

In addition, the method is based on the idea that a tire parameter can certainly already have a value of a validity parameter. For example, this can be any (preset) value, e.g., a value of 0 or the like. The value of the validity parameter can also be a date. The value can be, e.g., the date on which the tire was last inspected. The method is now based on the idea that a change in the value of the validity parameter from the previously stored value of the validity parameter to a then changed value of the validity parameter is utilized in order to determine that the detected tire parameter is in order, that is to say is valid, and therefore the tire parameter can be trusted. For example, the previously set value of the validity parameter can have the value 0. This value is now, e.g., changed by the workshop to 1. Alternatively, the previously set value of the validity parameter was the date of the last tire inspection and this value is now changed, for example, to the date of the current tire inspection. Embodiments of the present application are based on the idea that such a change in the value of the validity parameter is utilized in order to determine the validity of the detected tire parameter. In other words, a tire parameter which is communicated to an electronic control system would not be valid if no change has occurred to the value of the validity parameter compared to the previous value of the validity parameter. The detected tire parameter would then not be used.

In a preferred configuration, in the event that it has been determined that the detected tire parameter is valid, the method comprises the step, in accordance with which the tire parameter is used to establish a further tire parameter within a predefined time window. Specifically, the detected tire parameter can, for example, be a reference tire tread depth which was stored, for example, in the workshop or when the vehicle was delivered. Such a value can, e.g., be 4 mm. This value could then be used to establish an estimated tire tread depth of the tire, e.g., based on calculation models which are initialized by means of the reference tire tread depth. If it has then been determined that the reference tire tread depth is valid, said reference tire tread depth is used to establish the estimated tire tread depth. If, admittedly, it has been determined that the reference tire tread depth is not valid, then said reference tire tread depth is not established to establish the estimated tire tread depth. That is to say that the mathematical calculation model is not reinitialized.

As already mentioned, it is determined that the detected tire parameter is valid if the detected value of the validity parameter has changed compared to a previous value. It is particularly advantageous if the value of the validity parameter is changed, in particular in the event that the tire parameter is a reference tire tread depth, during a tire change. The tire change represents the changing of the (rubber) tire from the wheel rim. To this end, for example, the tire pressure must be completely released, the tire must be removed from the rim, a new tire must be fitted onto the rim and the tire pressure must be readjusted to the desired tire pressure.

According to an aspect of an embodiment, it is provided that during such a tire change, for example, by the vehicle's workshop, a change is made to the value of the validity parameter. In this case, the value of the validity parameter would be changed, e.g., from 0 to 1. The fact that the value of the validity parameter is now changed compared to the previous value means that the electronic control system would determine that the detected tire parameter, that is to say the reference tire tread depth of 4 mm in the specific example, is valid and may therefore be used, e.g., for the calculation of an estimated tire tread depth. That is to say that the electronic control system would start the initialization of the mathematical model.

It is particularly advantageous if, in this context, the value of the validity parameter is the date on which the tire change is performed. It is further advantageous if the predefined time window, within which the tire parameter may be used to establish the further tire parameter lies in a range of, e.g., 2 to 6 weeks. In the case of this advantageous configuration, it can now be defined, based on the date of the last tire change and based on the predefined time window, when the further tire parameter is to be established at the latest. That is to say that, in the specific example, the electronic control system would start the initialization of the mathematical model to establish the estimated tire tread depth within 2 to 6 weeks of the last tire change. In particular, this particularly preferred configuration makes it possible to estimate the tire tread depth of the tire correctly since the reference tire tread depth which is detected as valid is only used within the predefined time window to establish the estimated tire tread depth of the tire.

According to an aspect of an embodiment, there is provided a device for determining a validity of a tire parameter of a tire of a vehicle. The device comprises a tire parameter detection unit for detecting the tire parameter, a validity parameter detection unit for detecting a value of a validity parameter, the validity parameter being a measure of the validity of the tire parameter, and a control unit which is configured to determine the validity of the tire parameter if the detected value of the validity parameter is changed compared to a previous value of the validity parameter. The control unit is preferably further configured to carry out the steps of the method according to the embodiments according to the first aspect or configurations thereof.

### BRIEF DESCRIPTION OF THE DRAWINGS

Further features and objects of the present application will be understood to the person skilled in the art by executing the present teaching and viewing the appended drawings, wherein:

FIG. 1 is a flow chart illustrating a method of determining a validity of a tire parameter;

FIG. 2 is a flow chart of a method of determining a validity of a tire parameter;

FIG. 3 is a flow chart of a method of determining a validity of a tire parameter; and

FIG. 4 is a diagram illustrating a device for determining a validity of a tire parameter.

### DETAILED DESCRIPTION

Elements having a similar construction or function are provided with the same reference numerals across the figures.

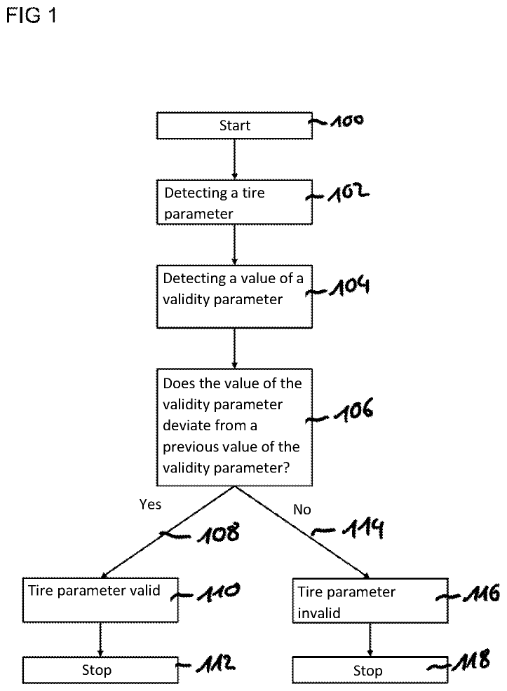

FIG. 1 shows a schematic representation of a flow chart of an embodiment of a method for determining a validity of a tire parameter.

The method starts with step 100. In the subsequent step 102, a tire parameter is detected. The tire parameter can, for example, be a reference tire tread depth of the tire of the vehicle. In the subsequent step 104, a value of a validity parameter is detected. The validity parameter indicates a measure of the validity of the detected tire parameter. In the subsequent step 106, it is determined whether the value of the detected validity parameter deviates from a previous value of the validity parameter. If the detected value of the validity parameter deviates from the previous value (branch 108), then it is determined in step 110 that the detected tire parameter is valid and the method stops with step 112. If, however, the value of the detected validity parameter does not deviate from the previous value (branch 114), then it is determined in step 116 that the detected tire parameter is not valid and the method stops with step 118. With the method according to FIG. 1, the detected tire parameter in the form of a change in the value of the validity parameter can, consequently, also be given the additional information to take along with it that the detected tire parameter is valid or not valid.

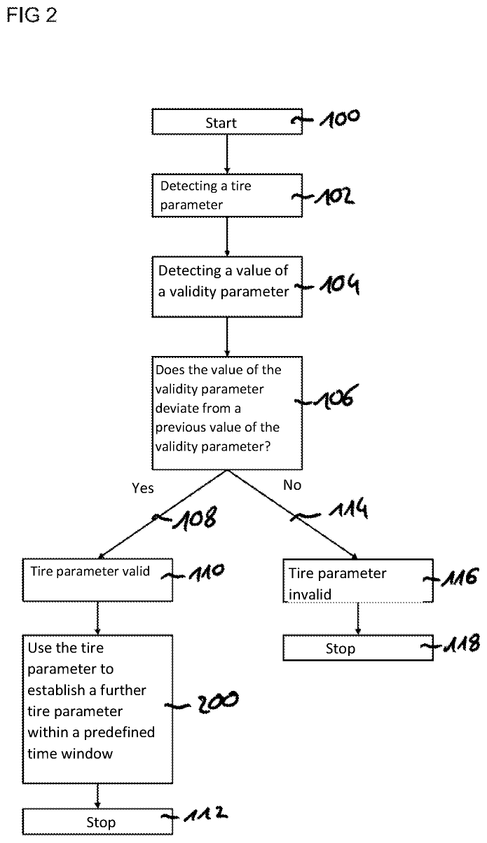

FIG. 2 shows a schematic representation of a flow chart of a further embodiment of the method. The method according to FIG. 2 has the steps 100 to 118 of the method according to FIG. 1. However, the method according to FIG. 2 differs from the method according to FIG. 1 in that if it has been determined, with step 110, that the detected tire parameter is valid, said detected tire parameter should be used to establish a further tire parameter, wherein it may only be used within a predefined time window. This is depicted in the flow chart of FIG. 2 by the additional step 200 between the steps 110 and 112. The predefined time window can, for example, lie in a range of 2 to 6 weeks and the further tire parameter mentioned can, for example, be an estimated tire tread depth which is established based on the detected reference tire tread depth.

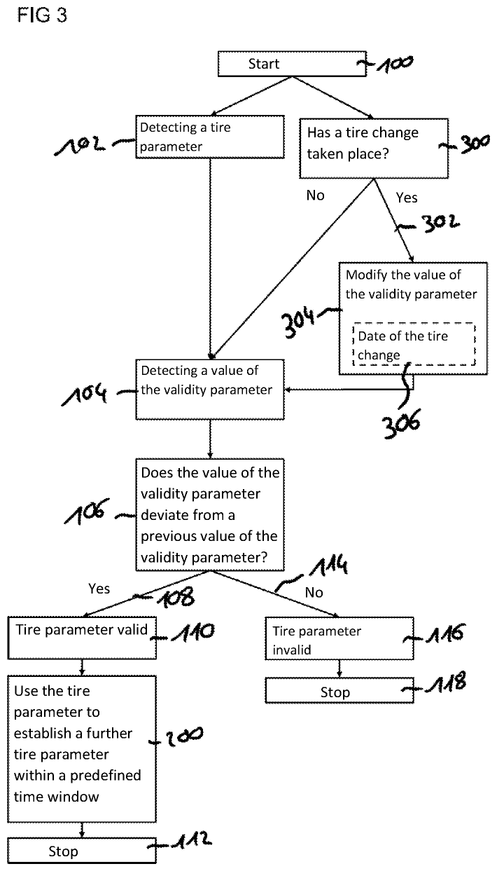

FIG. 3 shows a schematic representation of a flow chart of a further embodiment of the method. The method according to FIG. 3 is based on the method according to FIG. 2 and has, in the same way as the method according to FIG. 2, the steps 100 to 118 as well as the step 200. However, the method according to FIG. 3 differs from the method according to FIG. 2 in that it is determined, in a step 300, whether a tire change has taken place. A tire change, in this context, means removing and mounting a (rubber) tire from the rim or onto the rim, the consequence of which is that the tire pressure is released and the tire is refilled.

If it is determined that such a tire change has taken place (branch 302), the value of the validity parameter is then modified, in step 304, by entering the date of the day on which the tire change is performed (dashed box 306). The modification of the value of the validity parameter results in the value of the validity parameter being valid, and moreover has the advantage that an expiry date can then be ascertained in connection with the time window predefined in step 200, by when the detected tire parameter may be utilized to establish the further tire parameter.

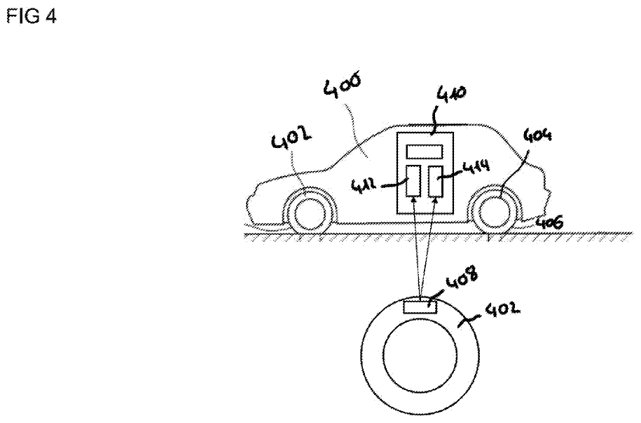

Reference is also made to FIG. 4, which shows a schematic representation of an embodiment of a device for determining a validity of a tire parameter of a tire 402 of a vehicle 400. The tire 402 has a rim 404 and rubber 406. The tire 402 additionally has a tire sensor 408 which detects a tire parameter of the tire 402. The tire sensor 408 is connected to a control unit 410 in terms of signaling and can transmit the detected tire parameter to the control unit 410. The tire sensor 408 can also transmit a validity parameter to the control unit 410. For this purpose, the control unit 410 has a tire parameter detection unit 412 for detecting the tire parameter as well as a validity parameter detection unit 414 for detecting the value of the validity parameter. Of course, it is also possible that the validity parameter can be entered directly into the validity parameter detection unit 414 without having to trouble the tire sensor 408. This can be effected, e.g., by an employee of a workshop. The control unit 410 is additionally configured to perform the steps mentioned in connection with FIGS. 1 to 3. Therefore, a device is created, which determines the validity of a tire parameter and optionally utilizes this for further assessments or steps.

1. A method of determining a validity of a tire parameter of tire of a vehicle, the method comprising:
detecting a value of a validity parameter of the tire parameter, the validity parameter indicating a degree of trustworthiness of the tire parameter for use by an electronic control system of the vehicle configured to analyze the tire of the vehicle;
determining whether the tire parameter is trustworthy based on the value of the validity parameter; and
analyzing the tire in a mathematical model using the tire parameter in response to determining the tire parameter is trustworthy and analyzing the tire in a mathematical model without using the tire parameter in response to determining the tire parameter is not trustworthy.

2. (canceled)

3. The method according to claim 1, wherein the value of the validity parameter is changed during installation of the tire on the vehicle.

4. The method according to claim 1, wherein the value of the validity parameter is a date on which the tire is installed on the vehicle.

5-6. (canceled)

7. The method according to claim 1, wherein the tire parameter is a tread depth of the tire.
